(19) United States
(12) Patent Application Publication
(10) Pub. No.: US 2025/0329596 A1
(43) Pub. Date: Oct. 23, 2025

(54) PACKAGE STRUCTURE INCLUDING AT LEAST TWO DICE, ASSEMBLY STRUCTURE AND METHOD OF MANUFACTURING THE SAME

(71) Applicant: NANYA TECHNOLOGY CORPORATION, NEW TAIPEI CITY (TW)

(72) Inventor: SHING-YIH SHIH, NEW TAIPEI CITY (TW)

(21) Appl. No.: 18/640,229

(22) Filed: Apr. 19, 2024

(51) Int. Cl. H01L 23/31; H01L 23/00; H01L 23/498; H01L 25/065

(52) U.S. Cl. CPC H01L 23/3128; H01L 23/49816; H01L 24/08; H01L 24/16; H01L 25/0655; H01L 2224/08146; H01L 2224/08225; H01L 2224/16104; H01L 2224/16146; H01L 2924/0665; H01L 2924/1431; H01L 2924/1434; H01L 2924/15311; H01L 2924/182

(57) ABSTRACT

A package structure, an assembly structure and a manufacturing method are provided. The package structure includes a molded structure, a first top die and a second top die. The molded structure includes a first electronic device, a second electronic device and an encapsulant encapsulating the first electronic device and the second electronic device. The first top die is electrically connected to the first electronic device and the second electronic device. The second top die is electrically connected to the second electronic device.

### TECHNICAL FIELD

The present disclosure relates to a package structure, an assembly structure and a method of manufacturing the same, and more particularly, to a package structure including at least one inactive element, an assembly structure including the package structure, and a method of manufacturing the same.

### DISCUSSION OF THE BACKGROUND

Semiconductor electronic devices are widely used in various electronic applications, and their dimensions are constantly being reduced to meet the demands of current applications. However, scaling down semiconductor electronic devices presents several challenges that affect their final electrical characteristics, quality, cost, and yield. As semiconductor electronic devices become smaller, they require multifunctional and high-volume data processing capabilities. Consequently, there is an increasing need to enhance the integration level of semiconductor devices used in these electronic devices. However, due to the limitations of semiconductor integration technology, it is challenging to meet all the required functions with just a single semiconductor chip. To address this issue, semiconductor packages have been developed, which involve including multiple semiconductor chips.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a package structure including a molded structure, a first top die and a second top die. The molded structure includes a first electronic device, a second electronic device and an encapsulant. The first electronic device includes a plurality of first upper pads. The second electronic device is disposed side by side with the first electronic device, and includes a plurality of first upper pads and a plurality of second upper pads. The encapsulant encapsulates the first electronic device and the second electronic device. The first top die is disposed over the molded structure, and includes a plurality of first bonding pads and a plurality of second bonding pads. The first bonding pads of the first top die are substantially aligned with and electrically connected to the first upper pads of the first electronic device respectively. The second bonding pads of the first top die are substantially aligned with and electrically connected to the first upper pads of the second electronic device respectively. The second top die is disposed over the molded structure, and includes a plurality of bonding pads substantially aligned with and electrically connected to the upper pads of the second electronic device respectively.

Another aspect of the present disclosure provides an assembly structure including a substrate, a molded structure, a first top die and a second top die. The molded structure is disposed over and electrically connected to the substrate. The molded structure includes a first electronic device, a second electronic device and an encapsulant. The second electronic device is disposed side by side with the first electronic device. A function of the first electronic device is different from a function of the second electronic device. The encapsulant encapsulates the first electronic device and the second electronic device. A top surface of the first electronic device and a top surface of the second electronic device are substantially coplanar with a top surface of the encapsulant. A bottom surface of the first electronic device and a bottom surface of the second electronic device are substantially coplanar with a bottom surface of the encapsulant. The first top die is disposed over the molded structure, and electrically connected to the first electronic device and the second electronic device respectively. The second top die is disposed over the molded structure, and electrically connected to the second electronic device.

Another aspect of the present disclosure provides a manufacturing method. The manufacturing method includes: forming a molded structure, wherein the molded structure includes a first electronic device, a second electronic device disposed side by side with the first electronic device, and an encapsulant encapsulating the first electronic device and the second electronic device, wherein a function of the first electronic device is different from a function of the second electronic device; electrically connecting a first top die to the first electronic device and the second electronic device; and electrically connecting a second top die to the second electronic device, wherein a function of the first top die is different from a function of the second top die.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

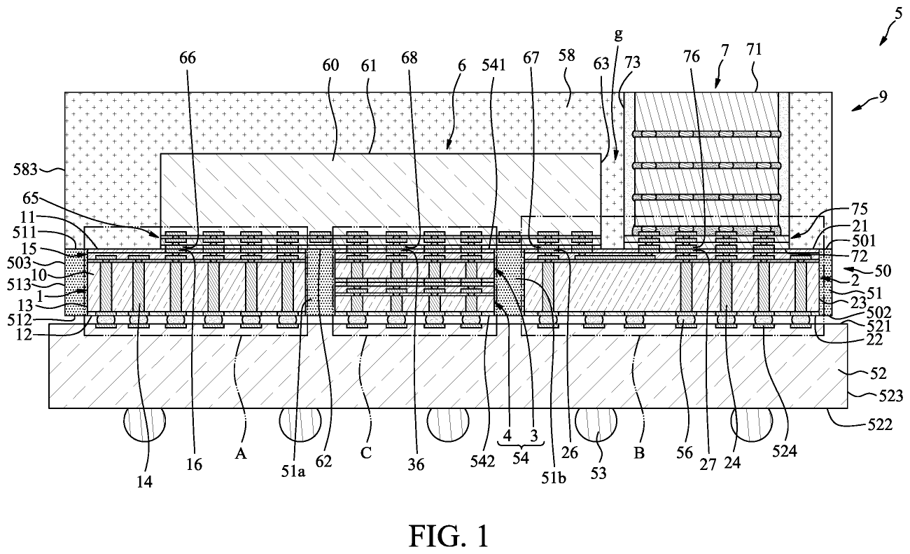

FIG. 1 is a schematic cross-sectional view of an assembly structure in accordance with some embodiments of the present disclosure.

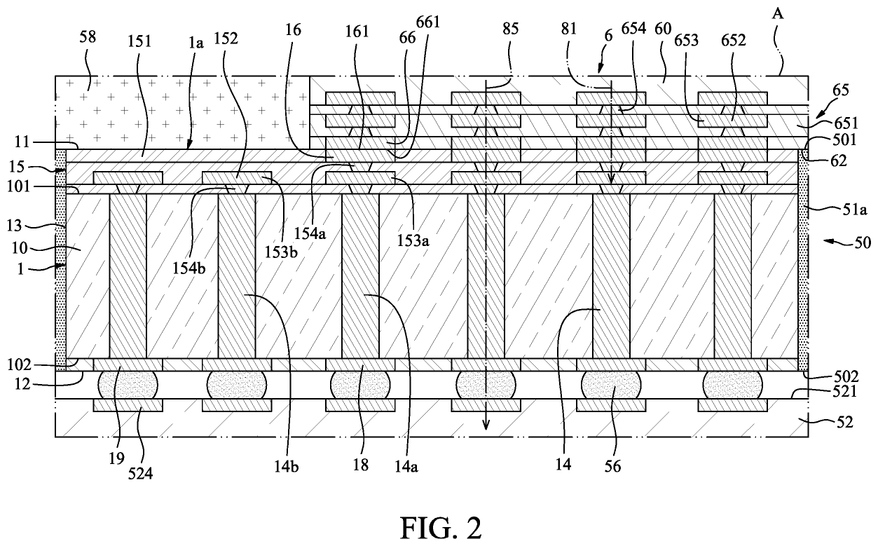

FIG. 2 is an enlarged view of an area “A” of FIG. 1.

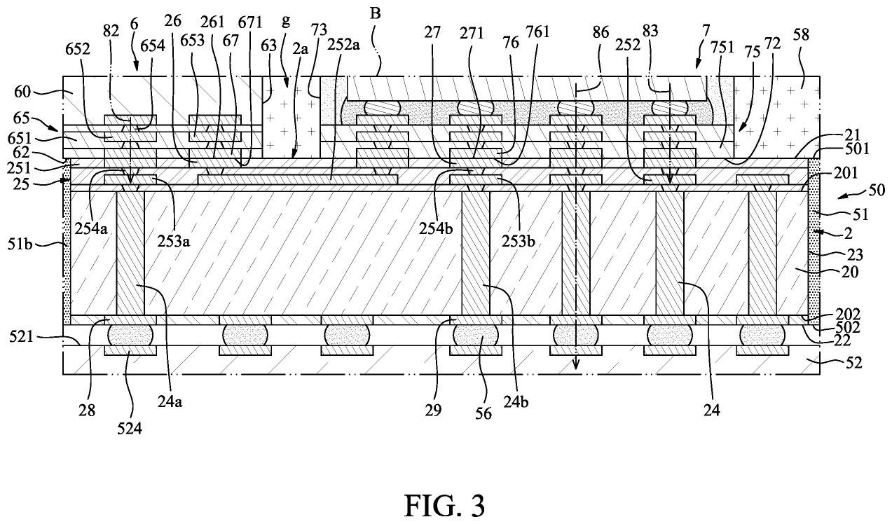

FIG. 3 is an enlarged view of an area “B” of FIG. 1.

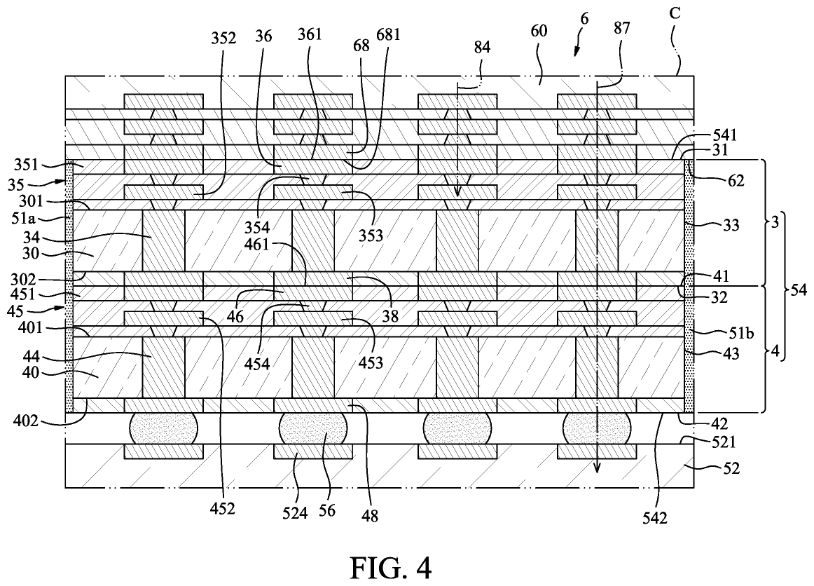

FIG. 4 is an enlarged view of an area “C” of FIG. 1.

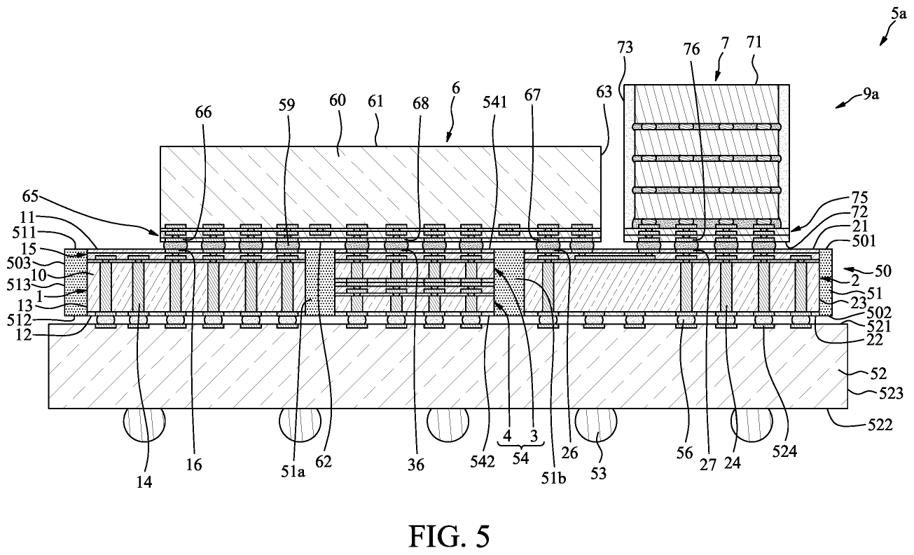

FIG. 5 is a schematic cross-sectional view of an assembly structure in accordance with some embodiments of the present disclosure.

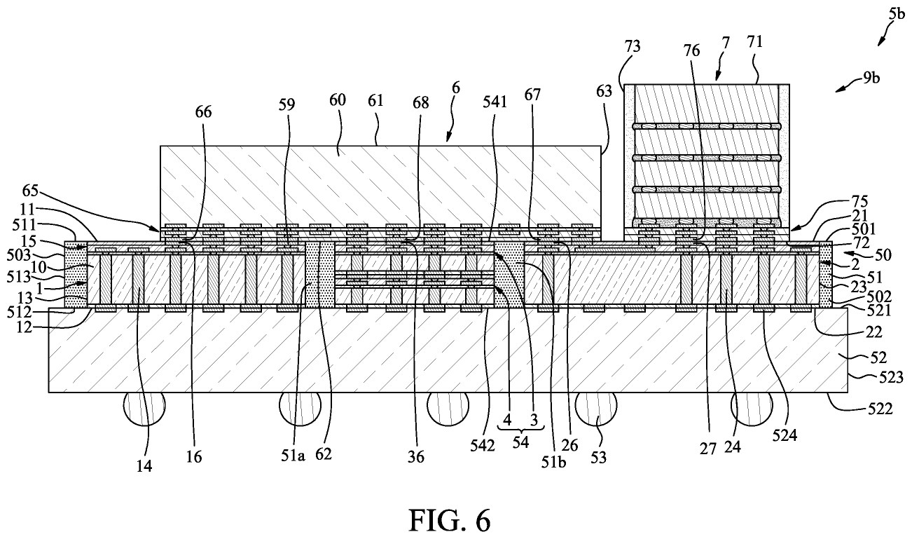

FIG. 6 is a schematic cross-sectional view of an assembly structure in accordance with some embodiments of the present disclosure.

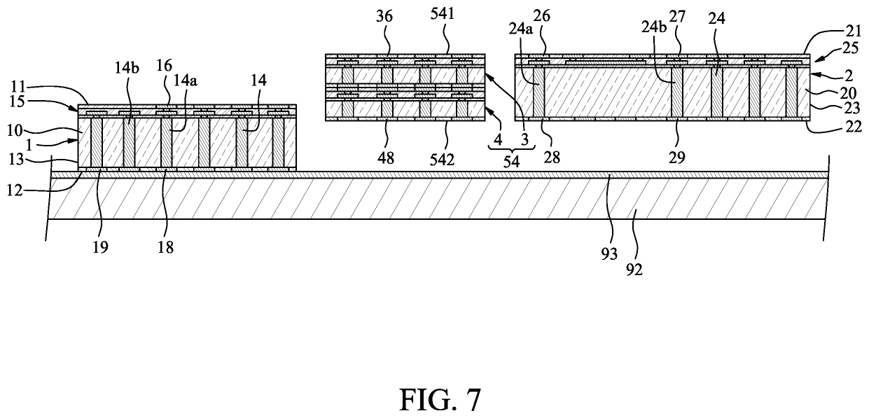

FIG. 7 to FIG. 15 illustrate various stages of a method of manufacturing an assembly structure, in accordance with some embodiments of the present disclosure.

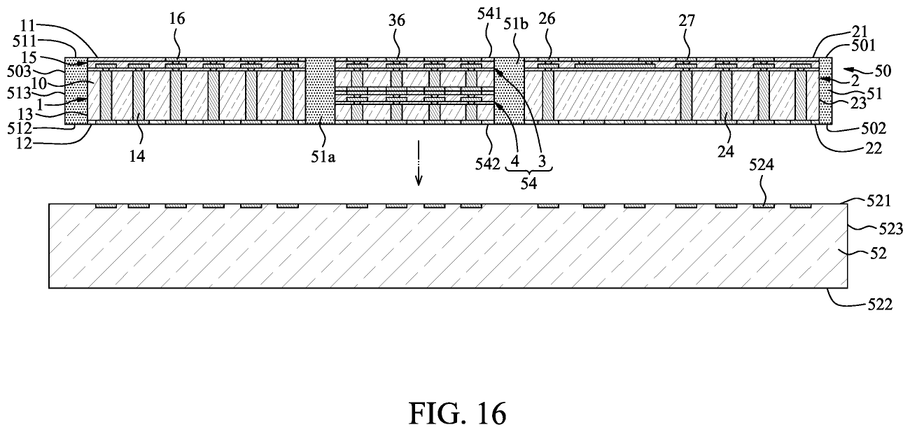

FIG. 16 to FIG. 18 illustrate various stages of a method of manufacturing an assembly structure, in accordance with some embodiments of the present disclosure.

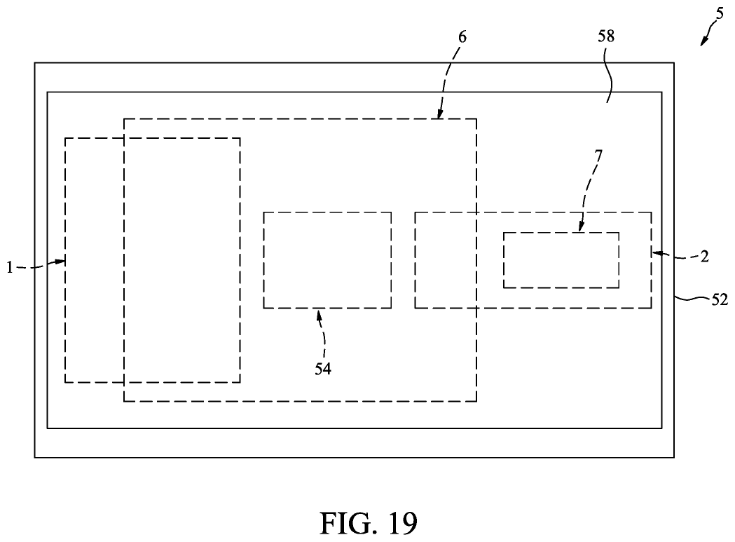

FIG. 19 is a top view of the assembly structure of FIG. 1.

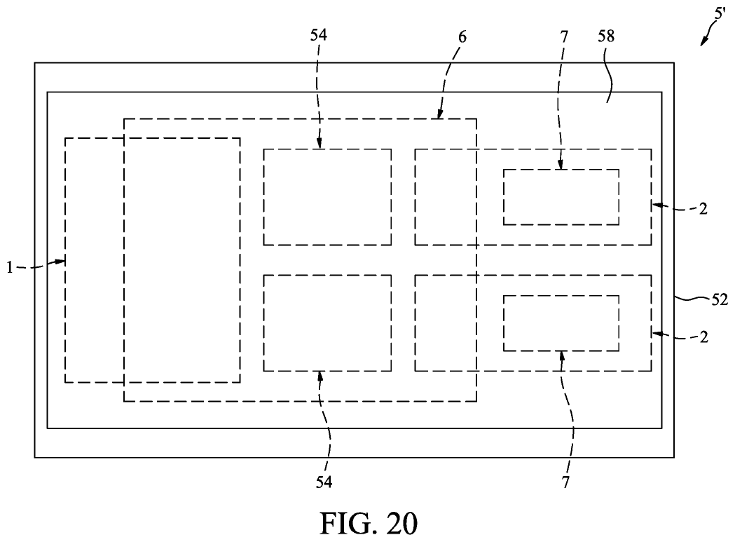

FIG. 20 is a top view of an assembly structure in accordance with some embodiments of the present disclosure.

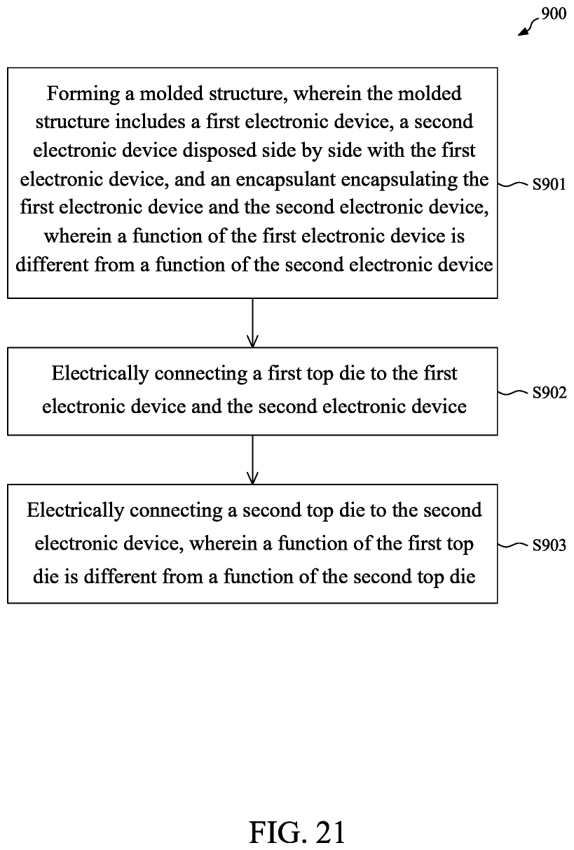

FIG. 21 is a flowchart of a method of manufacturing an assembly structure, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1 is a schematic cross-sectional view of an assembly structure 5 in accordance with some embodiments of the present disclosure. FIG. 2 is an enlarged view of an area “A” of FIG. 1. FIG. 3 is an enlarged view of an area “B” of FIG. 1. FIG. 4 is an enlarged view of an area “C” of FIG. 1. In some embodiments, the assembly structure 5 may be a semiconductor electronic device, a semiconductor electronic structure or a package structure. In some embodiments, the assembly structure 5 may include a package structure 9, a substrate 52, a plurality of bumps 56 and a plurality of external connectors 53.

The substrate 52 may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some embodiments, the substrate 52 may include a semiconductor-on-insulator substrate, such as a silicon-on-insulator (SOI) substrate, a silicon germanium-on-insulator (SGOI) substrate, or a germanium-on-insulator (GOI) substrate. In some embodiments, the substrate 52 may include organic material, glass, ceramic material or the like. For example, the substrate 52 may be made of a cured photoimageable dielectric (PID) material such as epoxy or polyimide (PI) including photoinitiators. For example, the substrate 52 may include a homogeneous material. For example, the material of the substrate 52 may include epoxy type FR5, FR4, Bismaleimide triazine (BT), print circuit board (PCB) material, Prepreg (PP), Ajinomoto build-up film (ABF) or other suitable materials.

The substrate 52 may have a first surface 521 (e.g., a top surface), a second surface 522 (e.g., a bottom surface) and a lateral surface 523. The second surface 522 (e.g., the bottom surface) may be opposite to the first surface 521 (e.g., the top surface). The lateral surface 523 may extend between the first surface 521 (e.g., the top surface) and the second surface 522 (e.g., the bottom surface). The substrate 52 may include a plurality of pads 524 exposed from the first surface 521 (e.g., the top surface) of the substrate 52.

The package structure 9 may be disposed over the first surface 521 of the substrate 52, and may be attached to and electrically connected to the pads 524 exposed from the first surface 521 of the substrate 52 through the bumps 56. Each of the bumps 56 may include a reflowable material such as a solder material including AgSn. The external connectors 53 may be disposed on the second surface 522 of the substrate 52 to provide electrical connections, for example, I/O connections, of the substrate 52. Each of the external connector 53 may include a reflowable material such as a solder ball including AgSn.

The package structure 9 may be a semiconductor package structure, a semiconductor electronic device, or a semiconductor electronic structure. The package structure 9 may include a molded structure 50, a first top die 6, a second top die 7 and a protection material 58.

The molded structure 50 may be disposed over and electrically connected to the substrate 52. The molded structure 50 may have a first surface 501 (e.g., a top surface), a second surface 502 (e.g., a bottom surface) and a lateral surface 503. The second surface 502 (e.g., the bottom surface) may be opposite to the first surface 501 (e.g., the top surface). The lateral surface 503 may extend between the first surface 501 (e.g., the top surface) and the second surface 502 (e.g., the bottom surface).

Referring to FIG. 1 to FIG. 4, the molded structure 50 may include a first electronic device 1, a second electronic device 2, an intermediate electronic device 54 and an encapsulant 51. The functions, structures and sizes of the first electronic device 1, the second electronic device 2 and the intermediate electronic device 54 may be different from each other. For example, the first electronic device 1 may include a semiconductor device or an interposer. The second electronic device 2 may include a semiconductor device or a bridge die such as a logic die or a controller. The intermediate electronic device 54 may include a semiconductor die or a chip, such as a cache memory chip (e.g., dynamic random access memory (DRAM) chip, or static random access memory (SRAM) chip, etc.).

The first electronic device 1, the second electronic device 2, and the intermediate electronic device 54 are disposed side by side, and the encapsulant 51 encapsulates the first electronic device 1, the second electronic device 2, and the intermediate electronic device 54. The first electronic device 1, the second electronic device 2, and the intermediate electronic device 54 may be attached to and electrically connected to the pads 524 of the substrate 52 through the bumps 56.

As shown in FIG. 1 and FIG. 2, the first electronic device 1 may have a first surface 11 (e.g., a top surface or an active surface), a second surface 12 (e.g., a bottom surface or a backside surface) and a lateral surface 13. The second surface 12 (e.g., the bottom surface) may be opposite to the first surface 11 (e.g., the top surface). The lateral surface 13 may extend between the first surface 11 (e.g., the top surface) and the second surface 12 (e.g., the bottom surface).

The first electronic device 1 may include a first main portion 10, a plurality of through vias 14, a first circuit structure 15, a plurality of first lower pads 18 and a plurality of second lower pads 19. A material of the first main portion 10 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The through vias 14 may extend through the first main portion 10, and may include a plurality of first through vias 14a and a plurality of second through vias 14b.

The first circuit structure 15 may be disposed on a top surface 101 of the first main portion 10. The first circuit structure 15 may include a dielectric structure 151 (including a plurality of dielectric layers), at least one circuit layer 152, a plurality of first inner pads 153a, a plurality of second inner pads 153b, a plurality of first inner vias 154a, a plurality of second inner vias 154b and a plurality of first upper pads 16. The circuit layer 152, the first inner pads 153a, the second inner pads 153b, the first inner vias 154a, the second inner vias 154b and the first upper pads 16 are embedded in the dielectric structure 151. A top surface 161 of the first upper pad 16 may be exposed from the first surface 11 of the first electronic device 1. Each of the first upper pads 16 may be a hybrid bonding (HB) pad, and may include Cu or Al.

The first through vias 14a, the first inner pads 153a, the first inner vias 154a and the first lower pads 18 may be disposed within a vertical projection of the first top die 6. The second through vias 14b, the second inner pads 153b, the second inner vias 154b and the second lower pads 19 may be disposed outside the vertical projection of the first top die 6.

The circuit layer 152 may horizontally connect the first inner pads 153a and the second inner pads 153b. The circuit layer 152 may be a fan-out redistribution layer. The first inner vias 154a may vertically connect the first inner pads 153a and the first upper pads 16. The first inner pads 153a may be electrically connected to a plurality of upper ends of the first through vias 14a through the first inner vias 154a. In some embodiments, a bottommost dielectric layer and the bottommost first inner vias 154a may be omitted, and the first inner pads 153a may directly contact the first through vias 14a and the top surface 101 of the first main portion 10.

The first lower pads 18 may be disposed under a bottom surface 102 of the first main portion 10, and electrically connected to a plurality of lower ends of the first through vias 14a. In some embodiments, the first lower pads 18 may directly contact the first through vias 14a and the bottom surface 102 of the first main portion 10.

The second inner pads 153b may be electrically connected to a plurality of upper ends of the second through vias 14b through the second inner vias 154b. In some embodiments, a bottommost dielectric layer and the bottommost second inner vias 154b may be omitted, and the second inner pads 153b may directly contact the second through vias 14b and the top surface 101 of the first main portion 10. The second lower pads 19 may be disposed under the bottom surface 102 of the first main portion 10, and electrically connected to a plurality of lower ends of the second through vias 14b. In some embodiments, the second lower pads 19 may directly contact the second through vias 14b and the bottom surface 102 of the first main portion 10.

As shown in FIG. 1 and FIG. 3, the second electronic device 2 may have a first surface 21 (e.g., a top surface or an active surface), a second surface 22 (e.g., a bottom surface or a backside surface) and a lateral surface 23. The second surface 22 (e.g., the bottom surface) may be opposite to the first surface 21 (e.g., the top surface). The lateral surface 23 may extend between the first surface 21 (e.g., the top surface) and the second surface 22 (e.g., the bottom surface).

The second electronic device 2 may include a second main portion 20, a plurality of through vias 24, a second circuit structure 25, at least one first lower pad 28 and a plurality of second lower pads 29. A material of the second main portion 20 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. A thickness of the second main portion 20 may be equal to a thickness of the first main portion 10.

The through vias 24 may extend through the second main portion 20, and may include at least one first through via 24a disposed under the first top die 6 and a plurality of second through vias 24b disposed under the second top die 7.

The second circuit structure 25 may be disposed on a top surface 201 of the second main portion 20. The second circuit structure 25 may include a dielectric structure 251 (including a plurality of dielectric layers), at least one circuit layer 252, at least one bridge circuit 252a, at least one first inner pad 253a, a plurality of second inner pads 253b, a plurality of first inner vias 254a, a plurality of second inner vias 254b, a plurality of first upper pads 26 and a plurality of second upper pads 27. The circuit layer 252, the bridge circuit 252a, the first inner pad 253a, the second inner pads 253b, the first inner vias 254a, the second inner vias 254b, the first upper pads 26 and the second upper pads 27 are embedded in the dielectric structure 251. A top surface 261 of the first upper pad 26 and a top surface 271 of the second upper pad 27 may be exposed from the first surface 21 of the second electronic device 2. Each of the first upper pads 26 and the second upper pads 27 may be a hybrid bonding (HB) pad, and may include Cu or Al.

The first through via 24a, the first inner pad(s) 253a, the first inner via(s) 254a and the first lower pad(s) 28 may be disposed within a vertical projection of the first top die 6. The second through vias 24b, the second inner pads 253b, the second inner vias 254b and the second lower pads 29 may be disposed within a vertical projection of the second top die 7.

The circuit layer 252 may horizontally connect the first inner pad(s) 253a and/or the second inner pads 253b. The bridge circuit 252a may electrically connect one of the first inner vias 254a and one of the second inner vias 254b. The bridge circuit 252a may be electrically connected to the first top die 6 and the second top die 7. The circuit layer 252 and the bridge circuit 252a may be at a same layer. Alternatively, the bridge circuit 252a may be a portion of the circuit layer 252.

The first inner vias 254a may vertically connect the first inner pads 253a and the first upper pads 26. The first inner pad 253a may be electrically connected to an upper end of the first through vias 24a through the first inner via 254a. In some embodiments, a bottommost dielectric layer and the bottommost first inner via 254a may be omitted, and the first inner pad 253a may directly contact the first through via 24a and the top surface 201 of the second main portion 20.

The first lower pad 28 may be disposed under a bottom surface 202 of the second main portion 20, and electrically connected to a lower end of the first through via 24a. In some embodiments, the first lower pad 28 may directly contact the first through via 24a and the bottom surface 202 of the second main portion 20.

The second inner vias 254b may vertically connect the second inner pads 253b and the second upper pads 27. The second inner pads 253b may be electrically connected to a plurality of upper ends of the second through vias 24b through the second inner vias 254b. In some embodiments, a bottommost dielectric layer and the bottommost second inner vias 254b may be omitted, and the second inner pads 253b may directly contact the second through vias 24b and the top surface 201 of the second main portion 20.

The second lower pads 29 may be disposed under the bottom surface 202 of the second main portion 20, and electrically connected to a plurality of lower ends of the second through vias 24b. In some embodiments, the second lower pads 19 may directly contact the second through vias 24b and the bottom surface 202 of the second main portion 20.

As shown in FIG. 1 and FIG. 4, the intermediate electronic device 54 may be disposed between the first electronic device 1 and the second electronic device 2. The intermediate electronic device 54 may have a first surface 541 (e.g., a top surface), a second surface 542 (e.g., a bottom surface) opposite to the first surface 541 (e.g., the top surface).

The encapsulant 51 may include a first portion 51a and a second portion 51b. The first portion 51a of the encapsulant 51 may be disposed between the intermediate electronic device 54 and the first electronic device 1. The second portion 51b of the encapsulant 51 may be disposed between the intermediate electronic device 54 and the second electronic device 2.

The intermediate electronic device 54 may include a third electronic device 3 stacked on a fourth electronic device 4. The third electronic device 3 may be electrically connected to the fourth electronic device 4 by hybrid bonding.

The third electronic device 3 may have a first surface 31 (e.g., a top surface or an active surface), a second surface 32 (e.g., a bottom surface or a backside surface) and a lateral surface 33. The second surface 32 (e.g., the bottom surface) may be opposite to the first surface 31 (e.g., the top surface). The lateral surface 33 may extend between the first surface 31 (e.g., the top surface) and the second surface 32 (e.g., the bottom surface).

The third electronic device 3 may include a third main portion 30, a plurality of third through vias 34, a third circuit structure 35, and a plurality of third lower pads 38. A material of the third main portion 30 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The third through vias 34 may extend through the third main portion 30. The third circuit structure 35 may be disposed on a top surface 301 of the third main portion 30. The third circuit structure 35 may include a dielectric structure 351 (including a plurality of dielectric layers), at least one circuit layer 352, a plurality of third inner pads 353, a plurality of third inner vias 354 and a plurality of third upper pads 36. The circuit layer 352, the third inner pads 353, the third inner vias 354 and the third upper pads 36 are embedded in the dielectric structure 351. A top surface 361 of the third upper pad 36 may be exposed from the first surface 31 of the third electronic device 3 (i.e., the first surface 541 of the intermediate electronic device 54). Each of the third upper pads 36 may be a hybrid bonding (HB) pad, and may include Cu or Al.

The third through vias 34, the third inner pads 353, the third inner vias 354 and the third lower pads 38 may be disposed within a vertical projection of the first top die 6.

The circuit layer 352 may horizontally connect the third inner pads 353. The third inner vias 354 may vertically connect the third inner pads 353 and the third upper pads 36. The third inner pads 353 may be electrically connected to a plurality of upper ends of the third through vias 34 through the third inner vias 354. In some embodiments, a bottommost dielectric layer and the bottommost third inner vias 354 may be omitted, and the third inner pads 353 may directly contact the third through vias 34 and the top surface 301 of the third main portion 30.

The third lower pads 38 may be disposed under a bottom surface 302 of the third main portion 30, and electrically connected to a plurality of lower ends of the third through vias 34. In some embodiments, the third lower pads 38 may directly contact the third through vias 34 and the bottom surface 302 of the third main portion 30.

The fourth electronic device 4 may have a first surface 41 (e.g., a top surface or an active surface), a second surface 42 (e.g., a bottom surface or a backside surface) and a lateral surface 43. The second surface 42 (e.g., the bottom surface) may be opposite to the first surface 41 (e.g., the top surface). The lateral surface 43 may extend between the first surface 41 (e.g., the top surface) and the second surface 42 (e.g., the bottom surface).

The fourth electronic device 4 may include a fourth main portion 40, a plurality of fourth through vias 44, a fourth circuit structure 45, a plurality of fourth lower pads 48. A material of the fourth main portion 40 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The fourth through vias 44 may extend through the fourth main portion 40. The fourth circuit structure 45 may be disposed on a top surface 401 of the fourth main portion 40. The fourth circuit structure 45 may include a dielectric structure 451 (including a plurality of dielectric layers), at least one circuit layer 452, a plurality of fourth inner pads 453, a plurality of fourth inner vias 454 and a plurality of fourth upper pads 46. The circuit layer 452, the fourth inner pads 453, the fourth inner vias 454 and the fourth upper pads 46 are embedded in the dielectric structure 451. A top surface 461 of the fourth upper pad 46 may be exposed from the first surface 41 of the fourth electronic device 4. Each of the fourth upper pads 46 may be a hybrid bonding (HB) pad, and may include Cu or Al.

The fourth upper pads 46 of the fourth electronic device 4 may be attached to the third lower pads 38 of the third electronic device 3 by metal-to-metal bonding. Thus, the fourth upper pads 46 of the fourth electronic device 4 may be substantially aligned with and electrically connected to the third lower pads 38 of the third electronic device 3 respectively. The fourth through vias 44, the fourth inner pads 453, the fourth inner vias 454 and the fourth lower pads 48 may be disposed within a vertical projection of the first top die 6.

The circuit layer 452 may horizontally connect the fourth inner pads 453. The fourth inner vias 454 may vertically connect the fourth inner pads 453 and the fourth upper pads 46. The fourth inner pads 453 may be electrically connected to a plurality of upper ends of the fourth through vias 44 through the fourth inner vias 454. In some embodiments, a bottommost dielectric layer and the bottommost fourth inner vias 454 may be omitted, and the fourth inner pads 453 may directly contact the fourth through vias 44 and the top surface 401 of the fourth main portion 40.

The fourth lower pads 48 may be disposed under a bottom surface 402 of the fourth main portion 40, and electrically connected to a plurality of lower ends of the fourth through vias 44. In some embodiments, the fourth lower pads 48 may directly contact the fourth through vias 44 and the bottom surface 402 of the fourth main portion 40.

As shown in FIG. 1, the encapsulant 51 may have a first surface 511 (or top surface) (e.g., the first surface 501 of the molded structure 50), a second surface 512 (or bottom surface) (e.g., the second surface 502 of the molded structure 50) and a lateral surface 513 (e.g., the lateral surface 503 of the molded structure 50). The second surface 512 may be opposite to the first surface 511. The lateral surface 513 may extend between the first surface 511 and the second surface 512. A material of the encapsulant 51 may include a molding compound with or without fillers.

The top surface 11 of the first electronic device 1 and a top surface 21 of the second electronic device 2 may be substantially coplanar with the first surface 511 of the encapsulant 51. Further, the bottom surface 12 of the first electronic device 1 and the bottom surface 22 of the second electronic device 2 may be substantially coplanar with the second surface 512 of the encapsulant 51

As shown in FIG. 1 and FIG. 2, the first top die 6 may have a first surface 61 (e.g., a top surface or a backside surface), a second surface 62 (e.g., a bottom surface or an active surface) and a lateral surface 63. The second surface 62 (e.g., the bottom surface) may be opposite to the first surface 61 (e.g., the top surface). The lateral surface 63 may extend between the first surface 61 (e.g., the top surface) and the second surface 62 (e.g., the bottom surface).

The first top die 6 may include a semiconductor die or a chip, such as a signal processing die (e.g., digital signal processing (DSP) die), a logic die (e.g., application processor (AP), system-on-a-chip (SoC), central processing unit (CPU), graphics processing unit (GPU), application specific integrated circuit (ASIC) die, or microcontroller, etc.), a radio frequency (RF) die, a sensor die, a micro-electro-mechanical-system (MEMS) die, a front-end die (e.g., analog front-end (AFE) dies) or other active components.

The first top die 6 may include a main portion 60 and a circuit structure 65. A material of the main portion 60 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The circuit structure 65 may be disposed on the main portion 60. The circuit structure 65 may include a dielectric structure 651 (including a plurality of dielectric layers), at least one circuit layer 652, a plurality of inner pads 653, a plurality of inner vias 654, a plurality of first bonding pads 66, a plurality of second bonding pads 67 and a plurality of third bonding pads 68. The circuit layer 652, the inner pads 653, the inner vias 654, the first bonding pads 66, the second bonding pads 67 and the third bonding pads 68 are embedded in the dielectric structure 651. A bottom surface 661 of the first bonding pad 66, a bottom surface 671 of the second bonding pad 67 and a bottom surface 681 of the first bonding pad 66 may be exposed from the second surface 62 of the first top die 6. Each of the first bonding pads 66, the second bonding pads 67 and the third bonding pads 68 may be a hybrid bonding (HB) pad, and may include Cu or Al.

The circuit layer 652 may horizontally connect the inner pads 653. The inner vias 654 may vertically connect the inner pads 653 and the first bonding pads 66, the second bonding pads 67 and the third bonding pads 68.

The first top die 6 may be disposed over the molded structure 50. The first top die 6 may be electrically connected to the first electronic device 1, the second electronic device 2 and the intermediate electronic device 54 of the molded structure 50 by hybrid bonding. As shown in FIG. 2, the first bonding pads 66 of the first top die 6 may be substantially aligned with and electrically connected to the first upper pads 16 of the first electronic device 1 respectively. Thus, the first bonding pads 66 of the first top die 6 may be attached to the first upper pads 16 of the first electronic device 1 by metal-to-metal bonding. The dielectric structure 651 of the circuit structure 65 of the first top die 6 may be directly attached to or may directly contact the dielectric structure 151 of the first circuit structure 15 of the first electronic device 1.

Therefore, the first top die 6 may be electrically connected to the first electronic device 1 through a plurality of first vertical electrical paths 81 (or conduction paths) directly extending from the first top die 6 to the first electronic device 1. There may be no horizontal electrical path between the first top die 6 and the first electronic device 1. Further, the first top die 6 may be electrically connected to the substrate 52 through a plurality of fifth vertical paths 85 directly extending from the first top die 6 to the substrate 52. There may be no horizontal electrical path between the first top die 6 and the substrate 52.

As shown in FIG. 3, the second bonding pads 67 of the first top die 6 may be substantially aligned with and electrically connected to the first upper pads 26 of the second electronic device 2 respectively. Thus, the second bonding pads 67 of the first top die 6 may be attached to the first upper pads 26 of the second electronic device 2 by metal-to-metal bonding. The dielectric structure 651 of the circuit structure 65 of the first top die 6 may be directly attached to or may directly contact the dielectric structure 251 of the second circuit structure 25 of the second electronic device 2.

Therefore, the first top die 6 may be electrically connected to the second electronic device 2 through a plurality of second vertical electrical paths 82 directly extending from the first top die 6 to the second electronic device 2. There may be no horizontal electrical path between the first top die 6 and the second electronic device 2.

As shown in FIG. 4, the third bonding pads 68 of the first top die 6 may be substantially aligned with and electrically connected to the third upper pads 36 of the intermediate electronic device 54 or the third electronic device 3 respectively. Thus, the third bonding pads 68 of the first top die 6 may be attached to the third upper pads 36 of the intermediate electronic device 54 or the third electronic device 3 by metal-to-metal bonding. The dielectric structure 651 of the circuit structure 65 of the first top die 6 may be directly attached to or may directly contact the dielectric structure 351 of the third circuit structure 35 of the third electronic device 3.

Therefore, the first top die 6 may be electrically connected to the third electronic device 3 of the intermediate electronic device 54 through a plurality of fourth vertical electrical paths 84 directly extending from the first top die 6 to the third electronic device 3 of the intermediate electronic device 54. There may be no horizontal electrical path between the first top die 6 and the third electronic device 3 of the intermediate electronic device 54. Further, the first top die 6 may be electrically connected to the substrate 52 through a plurality of seventh vertical paths 87 directly extending from the first top die 6 to the substrate 52 through the intermediate electronic device 54. There may be no horizontal electrical path between the first top die 6 and the substrate 52.

As shown in FIG. 1 and FIG. 3, the second top die 7 may have a first surface 71 (e.g., a top surface), a second surface 72 (e.g., a bottom surface) and a lateral surface 73. The second surface 72 (e.g., the bottom surface) may be opposite to the first surface 71 (e.g., the top surface). The lateral surface 73 may extend between the first surface 71 (e.g., the top surface) and the second surface 72 (e.g., the bottom surface).

A function of the first top die 6 may be different from a function of the second top die 7. The second top die 7 may include a semiconductor device or a memory die such as high bandwidth memory (HBM) die. The second top die 7 may include a base carrier 75 (such as a substrate or a logic die), a plurality of memory dice stacked on the base carrier 75 and an encapsulant (e.g., a molding compound) encapsulating the memory dice and covering a portion of a top surface of the base carrier 75.

The base carrier 75 may include a dielectric structure 751 (including a plurality of dielectric layers) and a plurality of bonding pads 76. A bottom surface 761 of the bonding pad 76 may be exposed from the second surface 72 of the second top die 7. Each of the bonding pads 76 may be a hybrid bonding (HB) pad, and may include Cu or Al.

The second top die 7 may be disposed over the molded structure 50. The second top die 7 may be electrically connected to the second electronic device 2 of the molded structure 50 by hybrid bonding. As shown in FIG. 3, the bonding pads 76 of the second top die 7 may be substantially aligned with and electrically connected to the second upper pads 27 of the second electronic device 2 respectively. Thus, the bonding pads 76 of the second top die 7 may be attached to the second upper pads 27 of the second electronic device 2 by metal-to-metal bonding. The dielectric structure 751 of the base carrier 75 of the second top die 7 may be directly attached to or may directly contact the dielectric structure 251 of the second circuit structure 25 of the second electronic device 2.

Therefore, the second top die 7 may be electrically connected to the second electronic device 2 through a plurality of third vertical electrical paths 83 directly extending from the second top die 7 to the second electronic device 2. There may be no horizontal electrical path between the second top die 7 and the second electronic device 2. Further, the second top die 7 may be electrically connected to the substrate 52 through a plurality of sixth vertical paths 86 directly extending from the second top die 7 to the substrate 52. There may be no horizontal electrical path between the second top die 7 and the substrate 52.

As shown in FIG. 1 to FIG. 4, the top surfaces 161 of the first upper pads 16 of the first electronic device 1, the top surfaces 261 of the first upper pads 26 of the second electronic device 2, the top surfaces 271 of the second upper pads 27 of the second electronic device 2 and the top surfaces 361 of the third upper pad 36 of the third electronic device 3 are substantially coplanar with the first surface 511 of the encapsulant 51. In addition, the top surface 11 of the first electronic device 1, the top surface 21 of the second electronic device 2 and the top surface 541 of the intermediate electronic device 54 (i.e., the top surface 31 of the third electronic device 3) are substantially coplanar with the first surface 511 of the encapsulant 51. The bottom surface 12 of the first electronic device 1, the bottom surface 22 of the second electronic device 2 and the bottom surface 542 of the intermediate electronic device 54 (i.e., the bottom surface 42 of the fourth electronic device 4) are substantially coplanar with the second surface 512 of the encapsulant 51.

As shown in FIG. 1 and FIG. 3, the bridge circuit 252a of the second electronic device 2 may be configured to electrically connect the second bonding pads 67 of the first top die 6 and the bonding pads 76 of the second top die 7. A portion 2a of the second electronic device 2 may be exposed in a gap g between the first top die 6 and the second top die 7. The lateral surface 63 of the first top die 6 and the lateral surface 73 of the second top die 7 may contact the top surface 21 of the second electronic device 2.

As shown in FIG. 1 and FIG. 2, a portion 1a of the first electronic device 1 may extend beyond a vertical projection of the first top die 6. Thus, the first top die 6 may partially vertically overlap the first electronic device 1.

As shown in FIG. 1, the protection material 58 (e.g., a molding compound with or without fillers) may cover the first top die 6, the second top die 7 and the top surface 501 of the molded structure 50. Thus, the protection material 58 may directly contact the top surface 11 of the first electronic device 1 and the top surface 21 of the second electronic device 2 and the first surface 511 of the encapsulant 51.

In the embodiment illustrated in FIG. 1 to FIG. 4, the heterogeneous electronic devices (such as semiconductor chips or semiconductor dice) may be integrated in the assembly structure 5 and the package structure 9 without redistribution structure or interposer. For example, the first top die 6 and the second top die 7 may be communicated with each other through the second electronic device 2. In addition, the first top die 6 may be directly communicated with the substrate 52 through the first electronic device 1, the second electronic device 2 and the intermediate electronic device 54. Further, the second top die 6 may be directly communicated with the substrate 52 through the second electronic device 2. Therefore, the assembly structure 5 and the package structure 9 may satisfy multiple required functions. Thus, the design flexibility is increased, and the manufacturing cost is reduced.

FIG. 5 is a schematic cross-sectional view of an assembly structure 5a in accordance with some embodiments of the present disclosure. The assembly structure 5a may be similar to the assembly structure 5 of FIG. 1 except for the structure of the package structure 9a. In the package structure 9a, the second surface 62 of the first top die 6 and the second surface 72 of the second top die 7 do not contact the top surface 501 of the molded structure 50. The protection material 58 may be omitted.

The first top die 6 may be electrically connected to the first electronic device 1, the second electronic device 2 and the intermediate electronic device 54 through a plurality of bumps such as solder materials 59. The second top die 7 may be electrically connected to the second electronic device 2 through the solder materials 59. The solder materials 59 may include a reflowable material such as AgSn. Thus, the first top die 6 and the second top die 7 are electrically connected to the molded structure 50 through solder bonding instead of hybrid bonding.

The first upper pads 16 of the first electronic device 1, the first upper pads 26 of the second electronic device 2, the second upper pads 27 of the second electronic device 2, the third upper pad 36 of the third electronic device 3, the first bonding pads 66, the second bonding pads 67 and the third bonding pads 68 of the first top die 6, and the bonding pads 76 of the second top die 7 be solder bonding pads.

FIG. 6 is a schematic cross-sectional view of an assembly structure 5b in accordance with some embodiments of the present disclosure. The assembly structure 5b may be similar to the assembly structure 5 of FIG. 1 except for the structure of the package structure 9b.

In the package structure 9b, the bumps 56 and the protection material 58 may be omitted. Thus, the molded structure 50 may be electrically connected to the substrate 52 by hybrid bonding. For example, the first electronic device 1, the fourth electronic device 4 of the intermediate electronic device 54 and the second electronic device 2 may be electrically connected to the substrate 52 by hybrid bonding instead of solder bonding.

The second surface 12 of the first electronic device 1, the second surface 42 of the fourth electronic device 4 (i.e., the second surface 542 of the intermediate electronic device 54) and the second surface 22 of the second electronic device 2 may directly contact the first surface 521 of the substrate 52.

The first lower pads 18 and the second lower pads 19 of the first electronic device 1, the first lower pads 28 and the second lower pads 29 of the second electronic device 2, the fourth lower pads 48 of the fourth electronic device 4, and the pads 524 of the substrate 52 may be hybrid bonding (HB) pads. Thus, the first lower pads 18 and the second lower pads 19 of the first electronic device 1, the first lower pads 28 and the second lower pads 29 of the second electronic device 2, and the fourth lower pads 48 of the fourth electronic device 4 may be attached to and electrically connected to the pads 524 of the substrate 52 through metal-to-metal bonding.

FIG. 7 to FIG. 15 illustrate various stages of a method of manufacturing an assembly structure 5, in accordance with some embodiments of the present disclosure.

Referring to FIG. 7 to FIG. 9, a molded structure 50 may be formed on a first carrier 92. The first carrier 92 may include a first release layer 93 thereon. Referring to FIG. 7, the first carrier 92 with the first release layer 93 thereon may be provided. In addition, a first electronic device 1, a second electronic device 2 and an intermediate electronic device 54 may be provided.

In some embodiments, only known good dice, e.g., the known good first electronic device 1, the known good second electronic device 2 and the known good intermediate electronic device 54 are used. In some embodiments, the size and the function of the first electronic device 1, the second electronic device 2 and the intermediate electronic device 54 may be different from each other.

The first electronic device 1 may be the same as the first electronic device 1 of FIG. 1 and FIG. 2. The first electronic device 1 may have a first surface 11, a second surface 12 and a lateral surface 13. The second surface 12 may be opposite to the first surface 11. The lateral surface 13 may extend between the first surface 11 and the second surface 12.

The first electronic device 1 may include a first main portion 10, a plurality of through vias 14, a first circuit structure 15, a plurality of first lower pads 18 and a plurality of second lower pads 19. The through vias 14 may extend through the first main portion 10, and may include a plurality of first through vias 14a and a plurality of second through vias 14b. The first circuit structure 15 may be disposed on a top surface 101 of the first main portion 10. The first circuit structure 15 may include a plurality of first upper pads 16. A top surface 161 of the first upper pad 16 may be exposed from the first surface 11 of the first electronic device 1.

The first lower pads 18 may be disposed under a bottom surface 102 of the first main portion 10, and electrically connected to a plurality of lower ends of the first through vias 14a. The second lower pads 19 may be disposed under the bottom surface 102 of the first main portion 10, and electrically connected to a plurality of lower ends of the second through vias 14b.

The second electronic device 2 may be the same as the second electronic device 2 of FIG. 1 and FIG. 3. The second electronic device 2 may have a first surface 21, a second surface 22 and a lateral surface 23. The second surface 22 may be opposite to the first surface 21. The lateral surface 23 may extend between the first surface 21 and the second surface 22.

The second electronic device 2 may include a second main portion 20, a plurality of through vias 24, a second circuit structure 25, at least one first lower pad 28 and a plurality of second lower pads 29. The through vias 24 may extend through the second main portion 20, and may include at least one first through via 24a and a plurality of second through vias 24b.

The second circuit structure 25 may be disposed on a top surface 201 of the second main portion 20. The second circuit structure 25 may include a plurality of first upper pads 26 and a plurality of second upper pads 27. A top surface 261 of the first upper pad 26 and a top surface 271 of the second upper pad 27 may be exposed from the first surface 21 of the second electronic device 2.

The first lower pad 28 may be disposed under a bottom surface 202 of the second main portion 20, and electrically connected to a lower end of the first through via 24a. The second lower pads 29 may be disposed under the bottom surface 202 of the second main portion 20, and electrically connected to a plurality of lower ends of the second through vias 24b.

The intermediate electronic device 54 may be the same as the intermediate electronic device 54 of FIG. 1 and FIG. 4. The intermediate electronic device 54 may have a first surface 541, a second surface 542 opposite to the first surface 541. The intermediate electronic device 54 may include a third electronic device 3 stacked on a fourth electronic device 4. The third electronic device 3 may be electrically connected to the fourth electronic device 4 by hybrid bonding.

The third electronic device 3 may have a first surface 31, a second surface 32 and a lateral surface 33. The second surface 32 may be opposite to the first surface 31. The lateral surface 33 may extend between the first surface 31 and the second surface 32.

The third electronic device 3 may include a third main portion 30, a plurality of third through vias 34, a third circuit structure 35, and a plurality of third lower pads 38. The third through vias 34 may extend through the third main portion 30. The third circuit structure 35 may be disposed on a top surface 301 of the third main portion 30. A top surface 361 of the third upper pad 36 may be exposed from the first surface 31 of the third electronic device 3. The third lower pads 38 may be disposed under a bottom surface 302 of the third main portion 30, and electrically connected to a plurality of lower ends of the third through vias 34.

The fourth electronic device 4 may have a first surface 41, a second surface 42 and a lateral surface 43. The second surface 42 may be opposite to the first surface 41. The lateral surface 43 may extend between the first surface 41 and the second surface 42.

The fourth electronic device 4 may include a fourth main portion 40, a plurality of fourth through vias 44, a fourth circuit structure 45, a plurality of fourth lower pads 48. The fourth through vias 44 may extend through the fourth main portion 40. The fourth circuit structure 45 may be disposed on a top surface 401 of the fourth main portion 40. The fourth circuit structure 45 may include a plurality of fourth upper pads 46. A top surface 461 of the fourth upper pad 46 may be exposed from the first surface 41 of the fourth electronic device 4.

The fourth upper pads 46 of the fourth electronic device 4 may be attached to the third lower pads 38 of the third electronic device 3 by metal-to-metal bonding. Thus, the fourth upper pads 46 of the fourth electronic device 4 may be substantially aligned with and electrically connected to the third lower pads 38 of the third electronic device 3 respectively. The fourth lower pads 48 may be disposed under a bottom surface 402 of the fourth main portion 40, and electrically connected to a plurality of lower ends of the fourth through vias 44.

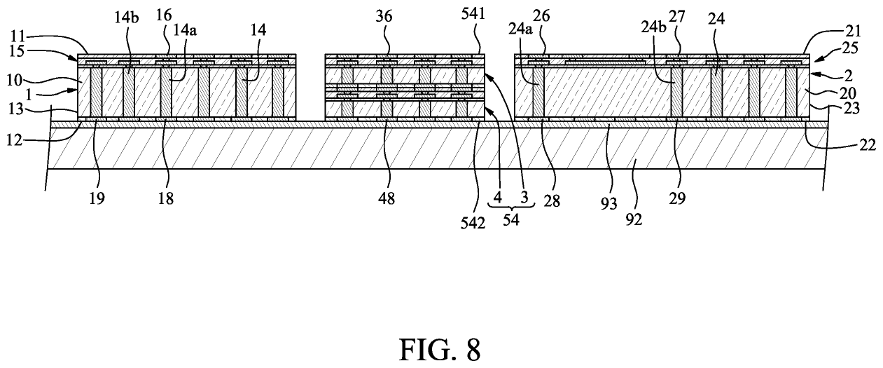

Referring to FIG. 8, the first electronic device 1, the second electronic device 2 and the intermediate electronic device 54 may be disposed side by side on the first release layer 93 of the first carrier 92. In some embodiments, the first electronic device 1, the second electronic device 2 and the intermediate electronic device 54 may be reconstructed or rearranged on the first release layer 93 of the first carrier 92. The second surface 12 of the first electronic device 1, the second surface 22 of the second electronic device 2 and the second surface 542 of the intermediate electronic device 54 may contact the first release layer 93. The intermediate electronic device 54 may be disposed between the first electronic device 1 and the second electronic device 2

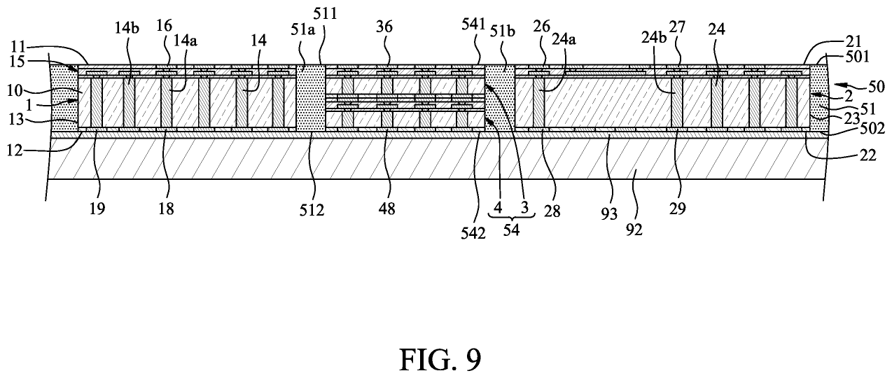

Referring to FIG. 9, an encapsulant 51 may be formed on the first release layer 93 of the first carrier 92 to encapsulate the first electronic device 1, the second electronic device 2 and the intermediate electronic device 54. The encapsulant 51 may be the same as the encapsulant 51 of FIG. 1.

Then, a grinding process may be conducted to form the molded structure 50 on the first carrier 92. The molded structure 50 may include the first electronic device 1, the second electronic device 2, the intermediate electronic device 54 and the encapsulant 51. The molded structure 50 may have a first surface 501 and a second surface 502 opposite to the first surface 501.

The encapsulant 51 may have a first surface 511 and a second surface 512 opposite to the first surface 511. The first surface 511 of the encapsulant 51 may be substantially coplanar with or aligned with the first surface 11 of the first electronic device 1, the first surface 21 of the second electronic device 2 and the first surface 541 of the intermediate electronic device 54. Thus, the first surface 501 of the molded structure 50 may include the first surface 511 of the encapsulant 51, the first surface 11 of the first electronic device 1, the first surface 21 of the second electronic device 2 and the first surface 541 of the intermediate electronic device 54.

In addition, the second surface 512 of the encapsulant 51 may be substantially coplanar with or aligned with the second surface 12 of the first electronic device 1, the second surface 22 of the second electronic device 2 and the second surface 542 of the intermediate electronic device 54. Thus, the second surface 502 of the molded structure 50 may include the second surface 512 of the encapsulant 51, the second surface 12 of the first electronic device 1, the second surface 22 of the second electronic device 2 and the second surface 542 of the intermediate electronic device 54.

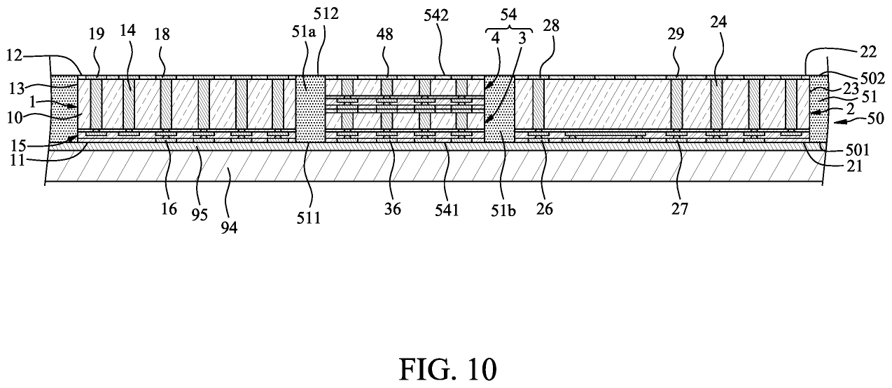

Referring to FIG. 10, the first surface 501 of the molded structure 50 may be attached to a second release layer 95 of a second carrier 94. Then, the first carrier 92 and the first release layer 93 may be removed from the molded structure 50, so as to expose the second surface 502 of the molded structure 50.

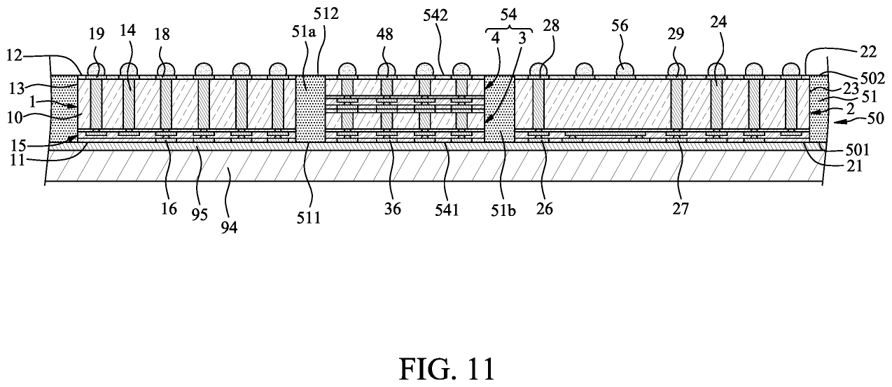

Referring to FIG. 11, a plurality of bumps 56 may be formed on the first lower pads 18 and the second lower pads 19 of the first electronic device 1, the first lower pads 28 and the second lower pads 29 of the second electronic device 2, and the fourth lower pads 48 of the fourth electronic device 4 of the intermediate electronic device 54.

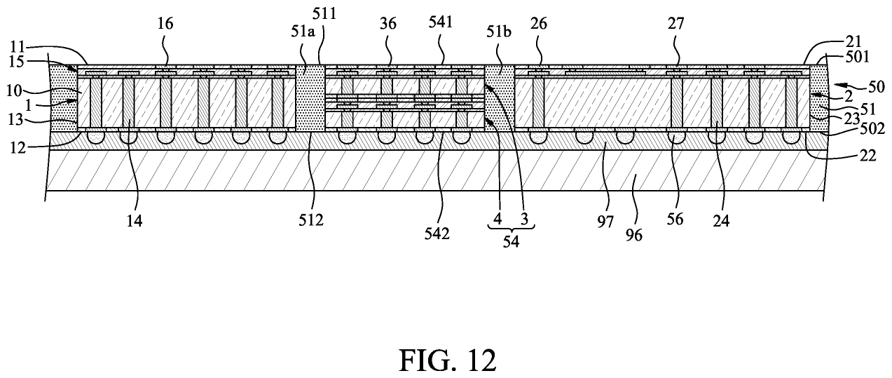

Referring to FIG. 12, the bumps 56 and the second surface 502 of the molded structure 50 may be attached to a third release layer 97 of a third carrier 96. Then, the second carrier 94 and the second release layer 95 may be removed from the molded structure 50, so as to expose the first surface 501 of the molded structure 50.

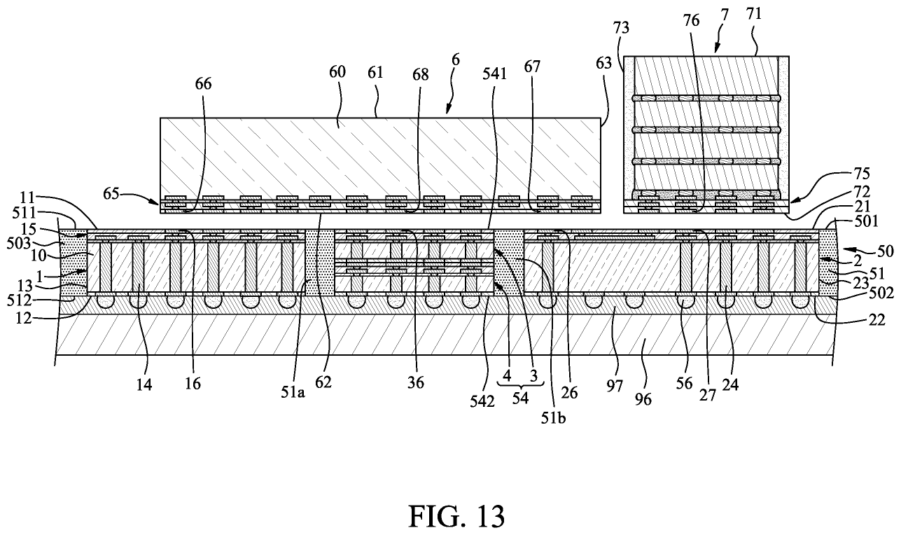

Referring to FIG. 13, a first top die 6 and a second top die 7 may be provided. A function and size of the first top die 6 may be different from a function and size of the second top die 7. The first top die 6 may be the same as the first top die 6 of FIG. 1. The first top die 6 may have a first surface 61, a second surface 62 and a lateral surface 63. The second surface 62 may be opposite to the first surface 61. The lateral surface 63 may extend between the first surface 61 and the second surface 62.

The first top die 6 may include a main portion 60 and a circuit structure 65. The circuit structure 65 may be disposed on the main portion 60. The circuit structure 65 may include a plurality of first bonding pads 66, a plurality of second bonding pads 67 and a plurality of third bonding pads 68. A bottom surface 661 of the first bonding pad 66, a bottom surface 671 of the second bonding pad 67 and a bottom surface 681 of the first bonding pad 66 may be exposed from the second surface 62 of the first top die 6.

The second top die 7 may be the same as the second top die 7 of FIG. 1. The second top die 7 may have a first surface 71, a second surface 72 and a lateral surface 73. The second surface 72 may be opposite to the first surface 71. The lateral surface 73 may extend between the first surface 71 and the second surface 72.

The second top die 7 may include a base carrier 75 (such as a substrate or a logic die), a plurality of memory dice stacked on the base carrier 75 and an encapsulant (e.g., a molding compound) encapsulating the memory dice and covering a portion of a top surface of the base carrier 75. The base carrier 75 may include a plurality of bonding pads 76. A bottom surface 761 of the bonding pad 76 may be exposed from the second surface 72 of the second top die 7.

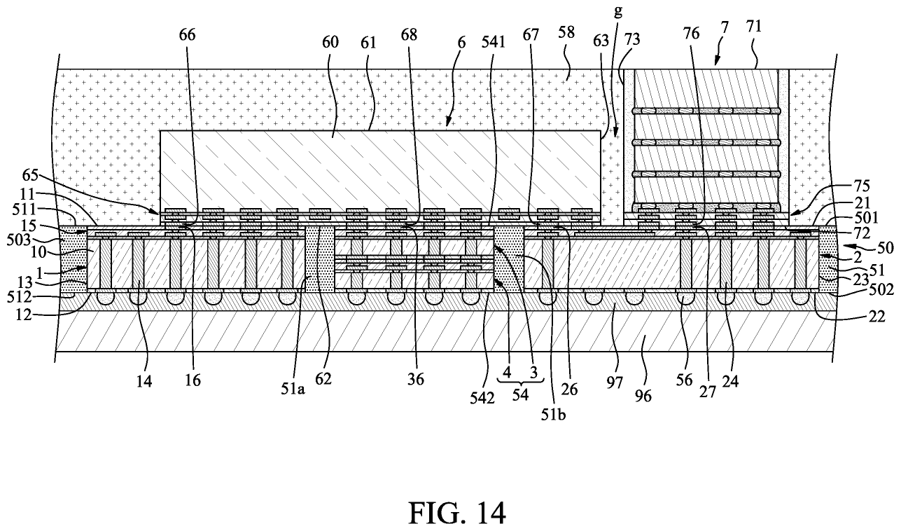

Referring to FIG. 14, the first top die 6 may be electrically connected to the first electronic device 1, the second electronic device 2 and the intermediate electronic device 54 of the molded structure 50 by hybrid bonding. The first bonding pads 66 of the first top die 6 may be substantially aligned with and electrically connected to the first upper pads 16 of the first electronic device 1 respectively. Thus, the first bonding pads 66 of the first top die 6 may be attached to the first upper pads 16 of the first electronic device 1 by metal-to-metal bonding.

The second bonding pads 67 of the first top die 6 may be substantially aligned with and electrically connected to the first upper pads 26 of the second electronic device 2 respectively. Thus, the second bonding pads 67 of the first top die 6 may be attached to the first upper pads 26 of the second electronic device 2 by metal-to-metal bonding.

The third bonding pads 68 of the first top die 6 may be substantially aligned with and electrically connected to the third upper pads 36 of the intermediate electronic device 54 or the third electronic device 3 respectively. Thus, the third bonding pads 68 of the first top die 6 may be attached to the third upper pads 36 of the intermediate electronic device 54 or the third electronic device 3 by metal-to-metal bonding.

In addition, the second top die 7 may be electrically connected to the second electronic device 2 of the molded structure 50 by hybrid bonding. The bonding pads 76 of the second top die 7 may be substantially aligned with and electrically connected to the second upper pads 27 of the second electronic device 2 respectively. Thus, the bonding pads 76 of the second top die 7 may be attached to the second upper pads 27 of the second electronic device 2 by metal-to-metal bonding.

Then, a protection material 58 may be formed to cover and contact the first top die 6, the second top die 7, a top surface 11 of the first electronic device 1, a top surface 21 of the second electronic device 2 and a top surface 511 of the encapsulant 51.

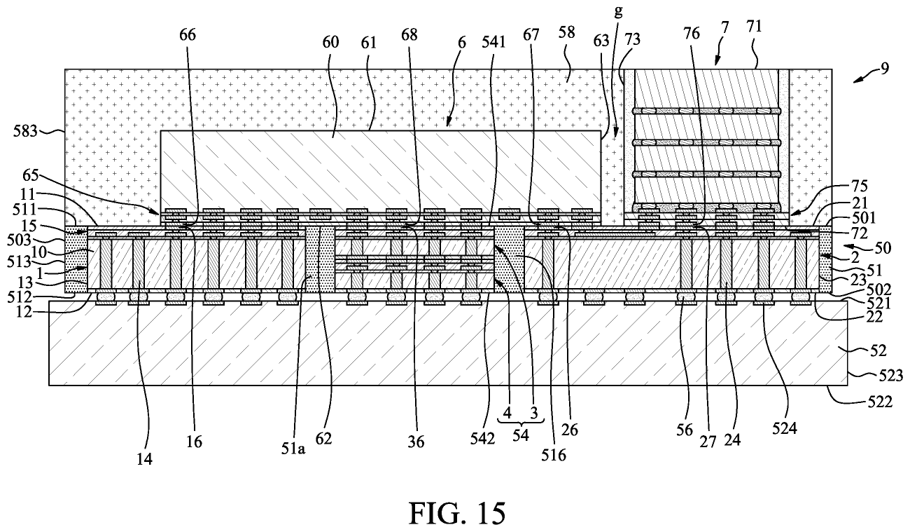

Referring to FIG. 15, a singulation process may be conducted to form a plurality of package structures 9. The package structure 9 may be the same as the package structure 9 of FIG. 1.

Then, the package structure 9 may be electrically connected to a plurality of pads 524 exposed from a first surface 521 (e.g., a top surface) of the substrate 52 through the bumps 56. For example, the molded structure 50 of the package structure 9 may be electrically connected to the pads 524 through the bumps 56.

Then, a plurality of external connectors 53 may be formed or disposed on a second surface 522 (e.g., a bottom surface) of the substrate 52, so as to obtain an assembly structure 5 as shown in FIG. 1.

FIG. 16 to FIG. 18 illustrate various stages of a method of manufacturing an assembly structure 5b, in accordance with some embodiments of the present disclosure. The initial several stages of the method corresponding to FIG. 16 to FIG. 18 are the same as, or at least similar to, the stages illustrated in FIG. 7 to FIG. 9. FIG. 16 depicts a stage subsequent to that depicted in FIG. 9.

Referring to FIG. 16, a singulation process is conducted to the molded structure 50, and the first carrier 92 and the first release layer 93 may be removed from the molded structure 50.

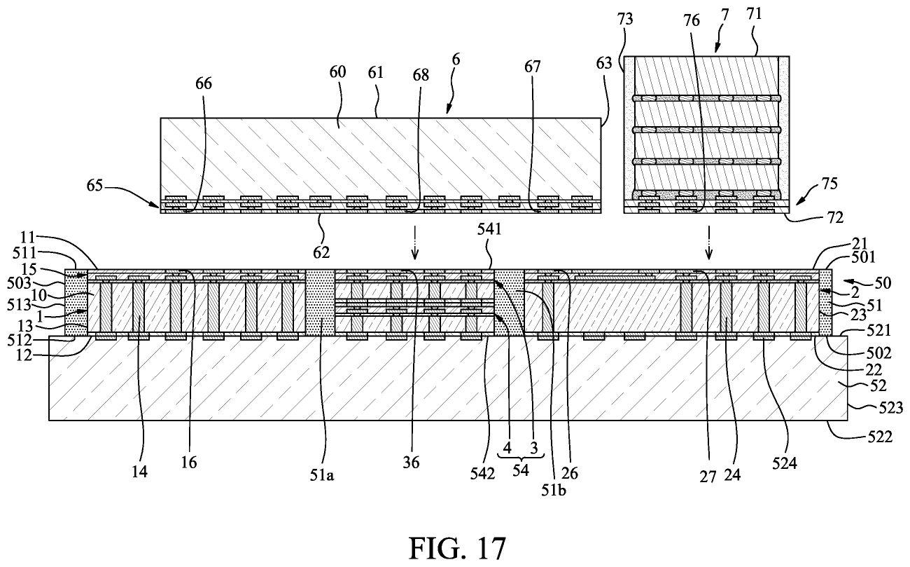

Referring to FIG. 17, the singulated molded structure 50 may be electrically connected to the substrate 52 by hybrid bonding. For example, the first electronic device 1, the fourth electronic device 4 of the intermediate electronic device 54 and the second electronic device 2 may be electrically connected to the substrate 52 by hybrid bonding instead of solder bonding. Thus, the second surface 12 of the first electronic device 1, the second surface 42 of the fourth electronic device 4 (i.e., the second surface 542 of the intermediate electronic device 54) and the second surface 22 of the second electronic device 2 may directly contact the first surface 521 of the substrate 52. The first lower pads 18 and the second lower pads 19 of the first electronic device 1, the first lower pads 28 and the second lower pads 29 of the second electronic device 2, and the fourth lower pads 48 of the fourth electronic device 4 may be attached to and electrically connected to the pads 524 of the substrate 52 through metal-to-metal bonding.

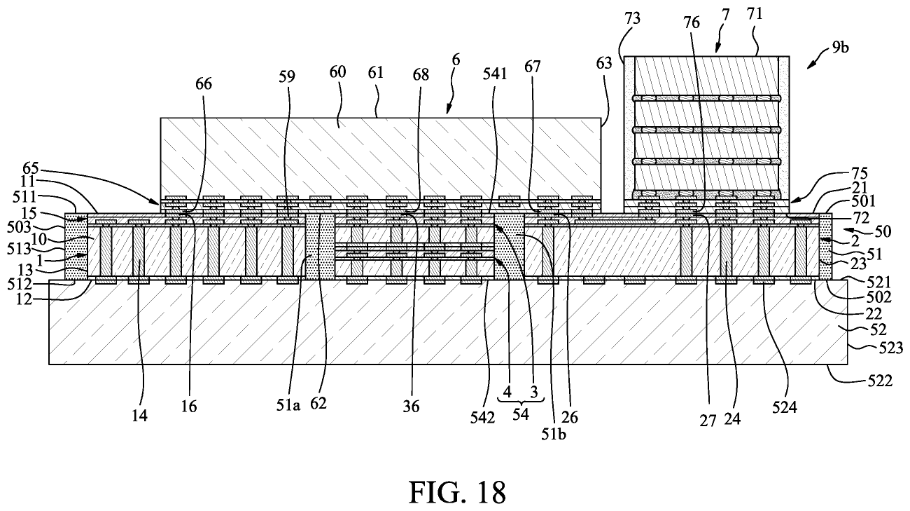

Referring to FIG. 18, the first top die 6 may be electrically connected to the first electronic device 1, the second electronic device 2 and the intermediate electronic device 54 of the molded structure 50 by hybrid bonding. The first bonding pads 66 of the first top die 6 may be substantially aligned with and electrically connected to the first upper pads 16 of the first electronic device 1 respectively. Thus, the first bonding pads 66 of the first top die 6 may be attached to the first upper pads 16 of the first electronic device 1 by metal-to-metal bonding.

The second bonding pads 67 of the first top die 6 may be substantially aligned with and electrically connected to the first upper pads 26 of the second electronic device 2 respectively. Thus, the second bonding pads 67 of the first top die 6 may be attached to the first upper pads 26 of the second electronic device 2 by metal-to-metal bonding.

The third bonding pads 68 of the first top die 6 may be substantially aligned with and electrically connected to the third upper pads 36 of the intermediate electronic device 54 or the third electronic device 3 respectively. Thus, the third bonding pads 68 of the first top die 6 may be attached to the third upper pads 36 of the intermediate electronic device 54 or the third electronic device 3 by metal-to-metal bonding.

In addition, the second top die 7 may be electrically connected to the second electronic device 2 of the molded structure 50 by hybrid bonding. The bonding pads 76 of the second top die 7 may be substantially aligned with and electrically connected to the second upper pads 27 of the second electronic device 2 respectively. Thus, the bonding pads 76 of the second top die 7 may be attached to the second upper pads 27 of the second electronic device 2 by metal-to-metal bonding.

Therefore, an assembly structure 5b as shown in FIG. 6 is obtained.

FIG. 19 is a top view of the assembly structure 5 of FIG. 1. The first top die 6 may overlap the first electronic device 1, the intermediate electronic device 54 and the second electronic device 2. The second top die 7 may only overlap the second electronic device 2.

FIG. 20 is a top view of an assembly structure 5′ in accordance with some embodiments of the present disclosure. The assembly structure 5′ may two second top dice 7, two intermediate electronic devices 54 and two second electronic devices 2. The first top die 6 may overlap the first electronic device 1, the two intermediate electronic device 54s and the two second electronic devices 2. Each of the second top dice 7 may only overlap each of the second electronic devices 2.

FIG. 21 illustrates a flow chart of a method 900 of manufacturing an assembly structure 5 in accordance with some embodiments of the present disclosure.

In some embodiments, the method 900 may include a step S901, forming a molded structure, wherein the molded structure includes a first electronic device, a second electronic device disposed side by side with the first electronic device, and an encapsulant encapsulating the first electronic device and the second electronic device, wherein a function of the first electronic device is different from a function of the second electronic device. For example, as shown in FIG. 9, a molded structure 50 may be formed. The molded structure 50 may include a first electronic device 1, a second electronic device 2 disposed side by side with the first electronic device 1. An encapsulant 51 may encapsulate the first electronic device 1 and the second electronic device 2. A function of the first electronic device 1 may be different from a function of the second electronic device 2.

In some embodiments, the method 900 may include a step S902, electrically connecting a first top die to the first electronic device and the second electronic device. For example, as shown in FIG. 14, a first top die 6 may be electrically connected to the first electronic device 1 and the second electronic device 2.

In some embodiments, the method 900 may include a step S903, electrically connecting a second top die to the second electronic device, wherein a function of the first top die is different from a function of the second top die. For example, as shown in FIG. 14, a second top die 7 may be electrically connected to the second electronic device 2. A function of the first top die 6 may be different from a function of the second top die 7.

One aspect of the present disclosure provides a package structure including a molded structure, a first top die and a second top die. The molded structure includes a first electronic device, a second electronic device and an encapsulant. The first electronic device includes a plurality of first upper pads. The second electronic device is disposed side by side with the first electronic device, and includes a plurality of first upper pads and a plurality of second upper pads. The encapsulant encapsulates the first electronic device and the second electronic device. The first top die is disposed over the molded structure, and includes a plurality of first bonding pads and a plurality of second bonding pads. The first bonding pads of the first top die are substantially aligned with and electrically connected to the first upper pads of the first electronic device respectively. The second bonding pads of the first top die are substantially aligned with and electrically connected to the first upper pads of the second electronic device respectively. The second top die is disposed over the molded structure, and includes a plurality of bonding pads substantially aligned with and electrically connected to the upper pads of the second electronic device respectively.

Another aspect of the present disclosure provides an assembly structure including a substrate, a molded structure, a first top die and a second top die. The molded structure is disposed over and electrically connected to the substrate. The molded structure includes a first electronic device, a second electronic device and an encapsulant. The second electronic device is disposed side by side with the first electronic device. A function of the first electronic device is different from a function of the second electronic device. The encapsulant encapsulates the first electronic device and the second electronic device. A top surface of the first electronic device and a top surface of the second electronic device are substantially coplanar with a top surface of the encapsulant. A bottom surface of the first electronic device and a bottom surface of the second electronic device are substantially coplanar with a bottom surface of the encapsulant. The first top die is disposed over the molded structure, and electrically connected to the first electronic device and the second electronic device respectively. The second top die is disposed over the molded structure, and electrically connected to the second electronic device.

Another aspect of the present disclosure provides a manufacturing method. The manufacturing method includes: forming a molded structure, wherein the molded structure includes a first electronic device, a second electronic device disposed side by side with the first electronic device, and an encapsulant encapsulating the first electronic device and the second electronic device, wherein a function of the first electronic device is different from a function of the second electronic device; electrically connecting a first top die to the first electronic device and the second electronic device; and electrically connecting a second top die to the second electronic device, wherein a function of the first top die is different from a function of the second top die.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A package structure, comprising:
a molded structure comprising:
a first electronic device including a plurality of first upper pads;
a second electronic device disposed side by side with the first electronic device, and including a plurality of first upper pads and a plurality of second upper pads; and
an encapsulant encapsulating the first electronic device and the second electronic device;
a first top die disposed over the molded structure, and including a plurality of first bonding pads and a plurality of second bonding pads, wherein the plurality of first bonding pads of the first top die are substantially aligned with and electrically connected to the plurality of first upper pads of the first electronic device respectively, wherein the plurality of second bonding pads of the first top die are substantially aligned with and electrically connected to the plurality of first upper pads of the second electronic device respectively; and
a second top die disposed over the molded structure, and including a plurality of bonding pads substantially aligned with and electrically connected to the plurality of second upper pads of the second electronic device respectively.

2. The package structure of claim 1, wherein a plurality of top surfaces of the plurality of first upper pads of the first electronic device, a plurality of top surfaces of the plurality of first upper pads of the second electronic device and a plurality of top surfaces of the plurality of second upper pads of the second electronic device are substantially coplanar with a top surface of the encapsulant.

3. The package structure of claim 1, wherein a top surface of the first electronic device and a top surface of the second electronic device are substantially coplanar with a top surface of the encapsulant, wherein a bottom surface of the first electronic device and a bottom surface of the second electronic device are substantially coplanar with a bottom surface of the encapsulant.

4. The package structure of claim 1, wherein the first top die is electrically connected to the first electronic device and the second electronic device by hybrid bonding, wherein the second top die is electrically connected to the second electronic device by hybrid bonding.

5. The package structure of claim 1, wherein the first top die is electrically connected to the first electronic device and the second electronic device through a plurality of solder materials, wherein the second top die is electrically connected to the second electronic device through a plurality of solder materials.

6. The package structure of claim 1, wherein the second electronic device further includes a bridge circuit configured to electrically connect the plurality of second bonding pads of the first top die and the plurality of bonding pads of the second top die.

7. The package structure of claim 1, wherein a portion of the second electronic device is exposed in a gap between the first top die and the second top die.

8. The package structure of claim 1, wherein a lateral surface of the first top die and a lateral surface of the second top die contact a top surface of the second electronic device.

9. The package structure of claim 1, wherein the first electronic device further includes:
a first main portion;
a plurality of first through vias extending through the first main portion;
a first circuit structure disposed on a top surface of the first main portion, and including a circuit layer, a plurality of first inner pads, a plurality of first inner vias and the plurality of first upper pads, wherein the circuit layer horizontally connects the plurality of first inner pads, wherein the plurality of first inner vias vertically connect the plurality of first inner pads and the plurality of first upper pads, wherein the plurality of first inner pads are electrically connected to a plurality of upper ends of the plurality of first through vias; and
a plurality of first lower pads disposed under a bottom surface of the first main portion, and electrically connected to a plurality of lower ends of the plurality of first through vias.

10. The package structure of claim 1, wherein the second electronic device further includes:
a second main portion;
at least one first through via disposed under the first top die, and extending through the second main portion;
a plurality of second through vias disposed under the second top die, and extending through the second main portion;
a second circuit structure disposed on a top surface of the second main portion, and including a circuit layer, a bridge circuit, at least one first inner pad, a plurality of second inner pads, a plurality of first inner vias, a plurality of second inner vias, the plurality of first upper pads and the plurality of second upper pads, wherein the circuit layer horizontally connects the at least one first inner pad and/or the plurality of second inner pads, and the bridge circuit electrically connects one of the plurality of first inner vias and one of the plurality of second inner vias, wherein the plurality of first inner vias vertically connect the at least one first inner pad and the plurality of first upper pads, wherein the at least one first inner pad is electrically connected to an upper end of the at least one first through via, wherein the plurality of second inner vias vertically connect the plurality of second inner pads and the plurality of second upper pads, wherein the plurality of second inner pads are electrically connected to a plurality of upper ends of the plurality of second through vias;
at least one first lower pad disposed under a bottom surface of the first main portion, and electrically connected to a lower end of the at least one first through via; and
a plurality of second lower pads disposed under the bottom surface of the second main portion, and electrically connected to a plurality of lower ends of the plurality of second through vias.

11. The package structure of claim 1, wherein the molded structure further includes:
an intermediate electronic device disposed between the first electronic device and the second electronic device, and including a plurality of third upper pads;
wherein the encapsulant further encapsulates the intermediate electronic device;
wherein first top die further includes a plurality of third bonding pads substantially aligned with and electrically connected to the plurality of third upper pads of the intermediate electronic device respectively.

12. The package structure of claim 11, wherein a first portion of the encapsulant is disposed between the intermediate electronic device and the first electronic device, and a second portion of the encapsulant is disposed between the intermediate electronic device and the second electronic device.

13. The package structure of claim 11, wherein the intermediate electronic device includes a third electronic device stacked on a fourth electronic device.

14. The package structure of claim 13, wherein the third electronic device is electrically connected to the fourth electronic device by hybrid bonding.

15. The package structure of claim 13, wherein the third electronic device includes:
a third main portion;
a plurality of third through vias extending through the third main portion;
a third circuit structure disposed on a top surface of the third main portion, and including a circuit layer, a plurality of third inner pads, a plurality of third inner vias and the plurality of third upper pads, wherein the circuit layer horizontally connects the plurality of third inner pads, wherein the plurality of third inner vias vertically connect the plurality of third inner pads and the plurality of third upper pads, wherein the plurality of third inner pads are electrically connected to a plurality of upper ends of the plurality of third through vias; and
a plurality of third lower pads disposed under a bottom surface of the third main portion, and electrically connected to a plurality of lower ends of the plurality of third through vias.

16. The package structure of claim 15, wherein the fourth electronic device includes:
a fourth main portion;
a plurality of fourth through vias extending through the fourth main portion;
a fourth circuit structure disposed on a top surface of the fourth main portion, and including a circuit layer, a plurality of fourth inner pads, a plurality of fourth inner vias and a plurality of fourth upper pads, wherein the plurality of fourth upper pads are substantially aligned with and electrically connected to the plurality of third lower pads of the third electronic device respectively, wherein the circuit layer horizontally connects the plurality of fourth inner pads, wherein the plurality of fourth inner vias vertically connect the plurality of fourth inner pads and the plurality of fourth upper pads, wherein the plurality of fourth inner pads are electrically connected to a plurality of upper ends of the plurality of fourth through vias; and
a plurality of fourth lower pads disposed under a bottom surface of the fourth main portion, and electrically connected to a plurality of lower ends of the plurality of fourth through vias.

17. The package structure of claim 11, wherein the intermediate electronic device includes a cache memory chip.

18. The package structure of claim 1, wherein a function of the first top die is different from a function of the second top die.

19. The package structure of claim 18, wherein the first top die includes a logic die, and the second top die includes a memory die.

20. The package structure of claim 1, wherein the second electronic device includes a logic die, and the first electronic device includes an interposer.
